(19) United States
(12) Patent Application Publication
(10) Pub. No.: US 2025/0180299 A1
(43) Pub. Date: Jun. 5, 2025

(54) HEAT PIPE

(71) Applicant: FURUKAWA ELECTRIC CO., LTD., Tokyo (JP)

(72) Inventor: Masahiro UEKUBO, Tokyo (JP)

(21) Appl. No.: 19/048,284

(22) Filed: Feb. 7, 2025

Related U.S. Application Data
(63) Continuation of application No. PCT/JP2024/022640, filed on Jun. 21, 2024.

(30) Foreign Application Priority Data
Jul. 18, 2023 (JP) 2023-116779

(51) Int. Cl. F28D 15/04; F28D 21/00

(52) U.S. Cl. CPC F28D 15/046; F28D 2021/0029

(57) ABSTRACT

A heat pipe is provided that that can raise the efficiency of circulation of a working fluid, and thereby possesses a superior thermal transport property. A heat pipe 1 includes a container 2 having an internal space S in which a working fluid F is sealed, the container 2 including: a evaporation portion 3 that evaporates a liquid-phase working fluid F_{L} to change phase to a gas-phase working fluid F_{g}; a condensation portion 4 arranged at a position that is separated from the evaporation portion 3, and condenses the gas-phase working fluid F_{g} to change phase into the liquid-phase working fluid F_{L}; and a middle portion 5 positioned between the evaporation portion 3 and the condensation portion 4; in which, viewing a transverse section of the evaporation portion 3, the heat pipe includes: a first sintered body layer 6 consisting of a sintered body of a first copper powder, and formed in a specific area on an inner circumferential surface 2a of the container 2; and a second sintered body layer 7 consisting of a sintered body of a second copper powder having a larger average particle size than the first copper powder, and formed annularly over an entirety of an inner circumferential surface 2a of the container 2, in a state in which the first sintered body layer 6 is interposed between the inner circumferential surface 2a of the container 2 and the second sintered body layer.

### TECHNICAL FIELD

The present invention relates to a heat pipe having a thermal transport property.

### BACKGROUND ART

In recent years, for electronic components such as semiconductor elements mounted on electric and electronic devices such as digital cameras and mobile phones, including notebook computers, since there is a trend of the heat quantity thereof increasing due to the high density installation accompanying increased functionality, it is important to adopt a configuration capable of efficiently cooling the electronic components. For example, a method of cooling electronic components using a heat pipe can be exemplified as a means for cooling electronic components.

Herein, heat pipes generally include a tubular container (container) having an internal space in which a working fluid is filled. The tubular container has, at one end portion, an evaporation portion that evaporates a liquid-phase working fluid to phase change into a gas-phase working fluid, and has, at the other end portion, a condensation portion that condenses the gas-phase working fluid to phase change to the liquid-phase working fluid. The working fluid having phase changed from the liquid phase to the gas phase in the evaporation portion flows from the evaporation portion to the condensation portion. The working fluid having phase changed from the gas phase to liquid phase in the condensation portion flows from the condensation portion to the evaporation portion. In this manner, a circulatory flow is formed by the circulation of the working fluid between the evaporation portion and the condensation portion within the tubular container, whereby heat transport is carried out between the evaporation portion and the condensation portion within the tubular container.

As a conventional heat pipe, for example, Patent Document 1 discloses a heat pipe including a pipe body having a hollow part in a sealed state, a porous metallic body layer disposed so as to be in contact with an inner circumferential surface of the pipe body, and a working fluid enclosed in the pipe body, in which the porous metallic body layer has a first porous portion partitioned in the circumferential direction thereof, and a second porous portion having a smaller porosity than this first porous portion. This heat pipe is said to migrate the liquid-phase working fluid mainly by the first porous portion, and achieve heat exchange between the pipe main body and the working fluid mainly by the second porous portion.

### CITATION LIST

### Patent Document

Patent Document 1: Japanese Unexamined Patent Application, Publication No. 2003-148886

### DISCLOSURE OF THE INVENTION

### Problems to be Solved by the Invention

In the heat pipe disclosed in Patent Document 1, the working fluid is phase changed from liquid phase to the gas phase in the second porous portion; however, in order to handle a further increase in heat quantity of an electronic device, it is necessary to efficiently circulate a greater amount of working fluid. Herein, it is possible to raise the efficiency of circulation of the working fluid if increasing the thickness of the second porous portion; however, since the hollow part in which the gas-phase working fluid circulates thereby becomes narrow, the thermal transport property of the heat pipe declines.

An object of the present invention is to provide a heat pipe which can raise the efficiency of circulation of the working fluid, and thereby possesses a superior thermal transport property.

### Means for Solving the Problems

In order to achieve the above object, the outline configuration of the present invention is as follows.

(1) A heat pipe includes a container having an internal space in which a working fluid is sealed, the container including: a evaporation portion that evaporates a liquid-phase working fluid to change phase to a gas-phase working fluid; a condensation portion arranged at a position that is separated from the evaporation portion, and condenses the gas-phase working fluid to change phase into the liquid-phase working fluid; and a middle portion positioned between the evaporation portion and the condensation portion; in which, viewing a transverse section of the heat pipe in the evaporation portion, the heat pipe includes: a first sintered body layer consisting of a sintered body of a first copper powder, and formed in a specific area on an inner circumferential surface of the container; and a second sintered body layer consisting of a sintered body of a second copper powder having a larger average particle size than the first copper powder, and formed annularly over an entirety of an inner circumferential surface of the container, in a state in which the first sintered body layer is interposed between the inner circumferential surface of the container and the second sintered body layer.

(2) In the heat pipe as described in the above (1), when viewing in a longitudinal section including a longitudinal direction of the heat pipe, an arrangement length of the first sintered body layer is longer than a longitudinal direction dimension of the evaporation portion, and an arrangement length of the second sintered body layer is longer than the arrangement length of the first sintered body layer.

(3) In the heat pipe as described in the above (2), the second sintered body layer terminates at any position of the middle portion.

(4) In the heat pipe as described in the above (3), the heat pipe is configured so that a liquid-phase working fluid that has phase changed in the condensation portion flows toward the evaporation portion by way of capillary force through internal voids of the second sintered body layer located in the middle portion, and flows through a contact interface between an outer circumferential surface of the second sintered body layer and an inner circumferential surface of the first sintered body layer from the second sintered body layer towards the first sintered body layer.

(5) In the heat pipe as described in any one of the above (1) to (4), the specific area includes an area of an inner circumferential surface that constitutes a portion of the container which opposes a heat source.

(6) In the heat pipe as described in any one of the above (1) to (5), a plurality of grooves extending along a longitudinal direction of the container is formed in the inner circumferential surface of the container.

(7) In the heat pipe as described in the above (6), the first sintered body layer is filled to also form in the grooves located in the specific area.

(8) In the heat pipe as described in the above (6) or (7), the second sintered body layer substantially separates vapor flow of a gas-phase working fluid that has phase changed in the evaporation portion, and a liquid flow of a liquid-phase working fluid that has phase changed in the condensation portion, and the liquid flow is divided into a channel passing through the plurality of grooves, and a channel through internal voids of the second sintered body layer.

### Effects of the Invention

According to the present invention, it is possible to provide a heat pipe which can raise the efficiency of circulation of the working fluid, and thereby possesses a superior thermal transport property.

### BRIEF DESCRIPTION OF THE DRAWINGS

FIGS. 1A, 1B and 1C provide drawings showing the internal structure of a heat pipe according to a first embodiment, with FIG. 1A being a longitudinal sectional view, FIG. 1B being a cross-sectional view when sectioning on the line I_{A}-I_{A} of FIG. 1A, and FIG. 1C being a cross-sectional view when sectioning on the line I_{B}-I_{B} of FIG. 1A;

FIG. 2 is a cross-sectional view for explaining the flow of working fluid occurring inside during operation of the heat pipe of FIGS. 1A, 1B and 1C;

FIGS. 3A, 3B and 3C provide drawings showing the internal structure of a heat pipe according to a second embodiment, with FIG. 3A being a longitudinal sectional view, FIG. 3B being a cross-sectional view when sectioning on the line II_{A}-II_{A} Of FIG. 3A, and FIG. 3C being a cross-sectional view when sectioning on the line II_{B}-II_{B} of FIG. 3A; and

FIGS. 4A and 4B provide transverse sectional views showing the internal structure of heat pipes according to an example of the present invention and a comparative example, with FIG. 4A being a transverse sectional view of a heat pipe according to an example of the present invention, and FIG. 4B being a transverse sectional view of a heat pipe according to a comparative example.

### PREFERRED MODE FOR CARRYING OUT THE INVENTION

Next, heat pipes according to several embodiments of the present invention will be described below.

### FIRST EMBODIMENT

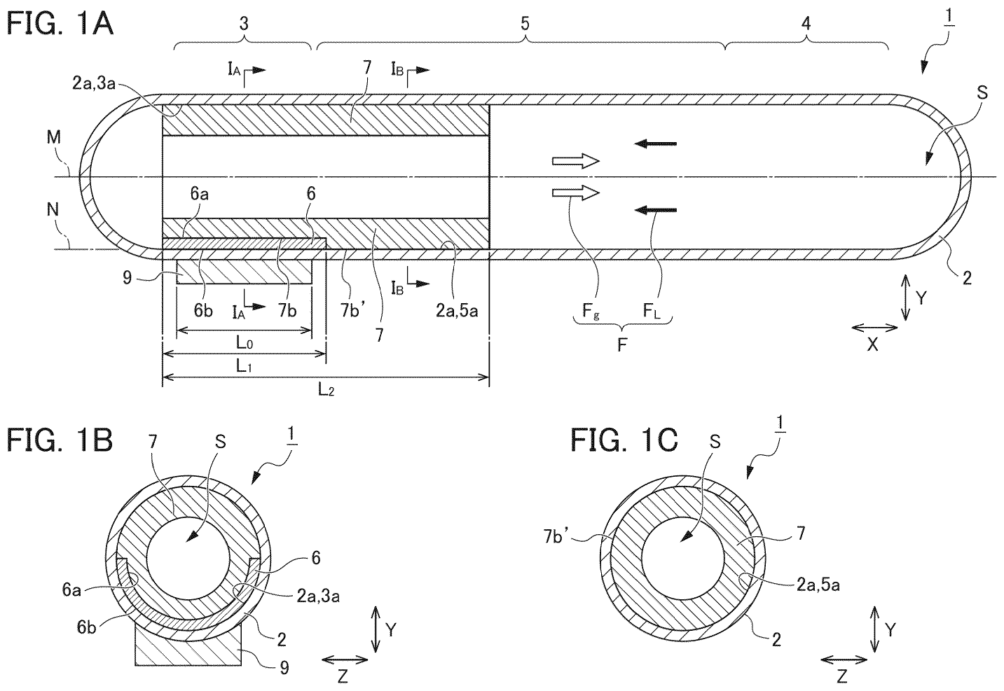

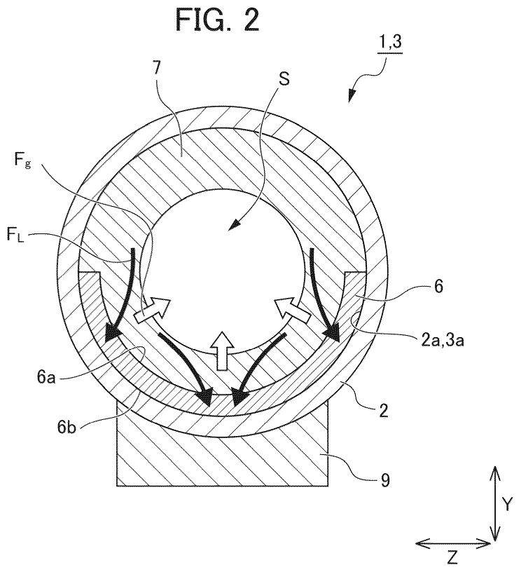

FIGS. 1A, 1B and 1C provide drawings showing the internal structure of a heat pipe according to a first embodiment, with FIG. 1A being a longitudinal section, FIG. 1B being a cross-sectional view when sectioning on the line I_{A}-I_{A} in FIG. 1A, and FIG. 1C being a cross-sectional view when sectioning on the line I_{B}-I_{B} Of FIG. 1A. On the other hand, FIG. 2 is a cross-sectional view for explaining the flow of the working fluid occurring inside during operation of the heat pipe of FIGS. 1A, 1B and 1C.

A heat pipe 1 includes a container 2 having an internal space S in which a working fluid F is sealed; an evaporation portion 3 which evaporates a liquid-phase working fluid F_{L} to change phase into a gas-phase working fluid F_{g}; a condensation portion 4 which is arranged at a position separated from the evaporation portion 3, and condenses the gas-phase working fluid F_{g} to change phase into the liquid-phase working fluid F_{L}; and a middle portion 5 positioned between the evaporation portion 3 and the condensation portion 4. This heat pipe 1 includes a first sintered body layer 6 made of a sintered body of a first copper powder and formed in a specific area on the inner circumferential surface 2a of the container 2 viewed in a transverse section of the evaporation portion 3, and a second sintered body layer 7 made of a sintered body of a second copper powder having an average particle size larger than that of the first copper powder and formed annularly over the entirety of the inner circumferential surface 2a of the container 2 in a state where the first sintered body layer 6 is interposed between the inner circumferential surface 2a of the container 2 and the second sintered body layer 7.

In the heat pipe 1, the second sintered body layer 7 formed of the second copper powder having an average particle size larger than that of the first copper powder is laminated on the inner circumferential surface 6a of the first sintered body layer 6 formed of the first copper powder, whereby the liquid-phase working fluid F_{L} is supplied to the first sintered body layer 6 through the voids in the second sintered body layer 7, and heat is transmitted to the liquid-phase working fluid F_{L} reaching the inner circumferential surface 6a of the first sintered body layer 6 and the voids formed therein, the liquid-phase working fluid F_{L} in the first sintered body layer 6 evaporates and phase changes into the gas-phase working fluid Fg, whereby heat can be exchanged between the working fluid F and the portion of the evaporation portion 3 where the first sintered body layer 6 is formed. For this reason, the heat conducted to a portion of the condensation portion 3 at which a first sintered body layer 6 is formed can be transferred to the condensation portion 4 in the form of the gas-phase working fluid F_{g}. In particular, this heat pipe 1, when viewing the condensation portion 3 in a transverse section perpendicular to the longitudinal direction X, has the first sintered body layer 6 formed in a specific region which is part of an inner circumferential surface 2a of the container 2, and a second sintered body layer 7 formed annularly along the entirety of the inner circumferential surface 2a of the container 2. The entirety of the surface of the first sintered body layer 6 enters a state covered by the second sintered body layer 7 in which the liquid-phase working fluid F_{L} flows, and the contact area between the first sintered body layer 6 and the second sintered body layer 7 increases, whereby the liquid-phase working fluid F_{L} is supplied in a wider range of the inner circumferential surface 6a of the first sintered body layer 6, and thus it is possible to promote circulation of the working fluid F. Together with this, in the inner circumferential surface 2a of the container 2, since the area of the portion in which circulation takes place, i.e. area in which the second sintered body layer 7 is laminated, becomes larger, relative to the area in which the first sintered body layer 6 is laminated, it is possible to raise the efficiency of circulation of the working fluid F.

In this way, since this heat pipe 1 can circulate the liquid-phase working fluid F_{L} efficiently, it is possible to provide a heat pipe which can raise the efficiency of circulation of the working fluid, and thus possesses superior thermal transport property.

### (Regarding Container Configuration)

The heat pipe 1 shown in FIGS. 1A, 1B, 1C and 2 includes the container 2 having an internal space S in which the working fluid F is sealed. In FIGS. 1A, 1B, 1C and 2, a tubular container is shown as an example of the container 2.

Herein, in addition to the linear shape shown in FIG. 1A, a shape having a bent portion as in an L shape or U shape and the like can be exemplified as the extended shape in the longitudinal direction X of the container 2, and the shape is not particularly limited. In addition, in addition to a substantially circular shape shown in FIGS. 1B and 1C, a flat shape, polygonal shapes such as a square, and the like can be exemplified as the outer surface profile shape of the container 2 when sectioned in an orthogonal direction to the longitudinal direction X of the container 2, and the shape is not particularly limited. The thickness of the container 2 is not particularly limited; however, it may be in the range of 0.05 mm to 1.0 mm, for example. The outer diameter dimension of the container 2 is not particularly limited; however, in the case of the container 2 being the outer surface contour shape which is substantially circular shown in FIGS. 1B and 1C, it is preferably in the range of 5 mm to 20 mm, for example.

The material of the container 2 is not particularly limited. Particularly in the case of using a water-based liquid as the working fluid F, it is preferable to use a metal material from the viewpoint of improving the wettability with the working fluid F. In particular, from the point of having superior thermal conductivity, it is possible to use copper, copper alloy or the like in the container 2, for example. In addition, from the point of weight reduction, it is possible to use aluminum, aluminum alloy and the like in the container 2, for example. Furthermore, from the point of having high strength, it is possible to use stainless steel and the like in the container 2, for example. In addition, tin, tin alloy, titanium, titanium alloy, nickel, nickel alloy and the like may be used in the container 2, for example, depending on the use situation.

### (Configurations of Evaporation Portion, Condensation Portion and Middle Portion)

The heat pipe 1 includes, in the container 2, the evaporation portion 3 which evaporates the liquid-phase working fluid F_{L} to change phase into the gas-phase working fluid F_{g}, the condensation portion 4 which is arranged at a position separated from the evaporation portion 3, and condenses the gas-phase working fluid F_{g} to change phase into the liquid-phase working fluid F_{L}; and the middle portion 5 positioned between the evaporation portion 3 and the condensation portion 4. Herein, the evaporation portion 3, the condensation portion 4 and the middle portion 5 can respectively be provided to parts along the longitudinal direction X of the container 2, as shown in FIG. 1A. The container 2 shown in FIG. 1A is configured as a sealed tube having the evaporation portion 3 at one end-side portion, having the condensation portion 4 at the other end-side portion, and having the middle portion 5 between the evaporation portion 3 and the condensation portion 4.

Thereamong, the evaporation portion 3 is formed at one end-side portion of the container 2 in FIG. 1A, and has a function of receiving heat (absorbing heat) from a thermally connected heat source 9. More specifically, the evaporation portion 3 evaporates the liquid-phase working fluid F_{L} to phase change to the gas-phase working fluid F_{g}, as illustrated in FIG. 2, for example, whereby heat received from the heat source 9 is absorbed as evaporative latent heat.

With the evaporation portion 3, the heat generated from the heat source 9 transmits to the first sintered body layer 6 via the container 2, and the heat further transmits from the first sintered body layer 6 to the second sintered body layer 7. On the other hand, as shown in FIG. 2, the liquid-phase working fluid F_{L} supplied from the condensation portion 4 to the evaporation portion 3 is supplied from the second sintered body layer 7 to the first sintered body layer 6 in the evaporation portion 3. For this reason, the phase change of the liquid-phase working fluid F_{L} to gas-phase working fluid F_{g} in the evaporation portion 3 is mainly carried out in the first sintered body layer 6; however, a part thereof may be carried out in the second sintered body layer 7. At this time, the gas-phase working fluid F_{g} generated by vaporization of the liquid-phase working fluid F_{L} in the first sintered body layer 6 migrates to the internal space S through the voids formed inside of the second sintered body layer 7.

In addition, the condensation portion 4 is arranged at a position separated from the evaporation portion 3, for example, arranged at the other end-side portion of the container 2 in FIGS. 1A, 1B and 1C. This condensation portion 4 has a function of radiating, by a heat exchanging means which is not shown, the evaporative latent heat possessed by the gas-phase working fluid F_{g} which phase changed and transported by the evaporation portion 3. In the condensation portion 4, the gas-phase working fluid F_{g} is condensed to phase change to a liquid-phase working fluid F_{L}, whereby the heat transported as condensation latent heat of the working fluid F is emitted to outside of the heat pipe 1.

### (Regarding Configuration of First Sintered Body Layer)

The first sintered body layer 6 consists of a sintered body of a first copper powder, and is a sintered body layer formed in a specific area on the inner circumferential surface 2a of the container 2, viewed in a transverse section of the evaporation portion 3 perpendicular to the longitudinal direction X of the heat pipe 1. The first sintered body layer 6 consists of a sintered body of a first copper powder having a smaller average particle size than the second sintered body layer 7 described later; therefore, the voids through which the liquid-phase working fluid F_{L} can flow is small, and the circulating velocity of the liquid-phase working fluid F_{L} is slow. In addition, since the first sintered body layer 6 is adjacent to the inner circumferential surface 3a of the evaporation portion 3 of the container 2, it is also a portion at which the temperature is likely to become relatively high. Therefore, as shown in FIG. 2, the flow of the working fluid F in the first sintered body layer 6 mainly includes the flow of the liquid-phase working fluid F_{L} supplied from the inner circumferential surface 6a side and entering the first sintered body layer 6; and the flow of the gas-phase working fluid F_{g} generated by the evaporation of the liquid-phase working fluid F_{L} entering the first sintered body layer 6, and migrating from the inside of the first sintered body layer 6 toward the internal space S via the inner circumferential surface 6a. According to such a first sintered body layer 6, since the heat received (absorbed) from the heat source (not shown) thermally connected to the container 2 is transmitted to the first sintered body layer 6, and the liquid-phase working fluid F_{L} is evaporated in a state where most of the heat remains in a specific area of the inner circumferential surface 2a of the container 2, the working fluid F can be phase changed into the gas phase efficiently. Herein, the specific area of the inner circumferential surface 2a of the container 2 can be defined as an area including the area of the inner circumferential surface 2a constituting a portion of the container 2 opposing the heat source 9.

The first sintered body layer 6 is provided at least to the evaporation portion 3, as shown in FIG. 1A. By providing such a first sintered body layer 6 to the evaporation portion 3, since the evaporation of the liquid-phase working fluid F_{L} is promoted in the evaporation portion 3, the heat received from the heat source 9 thermally connected with the evaporation portion 3 can be absorbed in more of the working fluid F as the evaporative latent heat.

Herein, the arrangement length L₁ of the first sintered body layer 6 is preferably longer than the longitudinal direction dimension L₀ of the evaporation portion 3, viewed in a longitudinal section including the longitudinal direction X of the heat pipe 1. The first sintered body layer 6 is thereby provided adjacent to both the inner circumferential surface 3a of the evaporation portion 3 and the inner circumferential surface 5a of the middle portion 5. By configuring the arrangement length L₁ of the first sintered body layer 6 in this way, it is possible to transmit the heat from the heat source 9 towards the side of the middle portion 5 to the first sintered body layer 6 to make absorb in the working fluid F. In particular, from the viewpoint of causing the heat from the heat source 9 toward the side of the middle portion 5 efficiently absorb to the working fluid F, the first sintered body layer 6 is more preferably at least arranged in an area of the inner circumferential surface 2a constituting a portion of the inner circumferential surface 2a of the container 2 opposing the heat source 9, and an area of the inner circumferential surface 2a of the container 2 adjacent to both sides of this area, viewing in a longitudinal section. On the other hand, the upper limit for the arrangement length L₁ of the first sintered body layer 6 is preferably 150 mm or less, from the viewpoint of facilitating the manufacture of the first sintered body layer 6 by the production method described later.

In addition, the first sintered body layer 6 preferably has a length of a portion of the inner circumferential surface 2a of the container 2 in which the first sintered body layer 6 is arranged longer than an area of the inner circumferential surface 2a constituting the portion opposing the heat source 9, viewed in a transverse section perpendicular to the longitudinal direction X of the heat pipe 1. In particular, the first sintered body layer 6, viewed in the transverse section, is more preferably arranged at least in an area of the inner circumferential surface 2a constituting the portion of inner circumferential surface 2a of the container 2 opposing the heat source 9, and an area on the inner circumferential surface 2a of the container 2 adjacent to both sides of this area. By configuring the first sintered body layer 6 in this way, it is possible to efficiently conduct the heat transmitted from the heat source 9 to the container 2 to the first sintered body layer 6, and make absorb to the working fluid F.

It should be noted that the inner circumferential surface in the present disclosure is a surface along the wall surface on the side of the internal space S. In addition, the outer circumferential surface in the present disclosure is a surface along the wall surface on a side distanced from the internal space S. In addition, the longitudinal direction dimension L₀ of the evaporation portion 3 can be defined as the size of the heat source 9 thermally connected to the heat pipe 1 along the longitudinal direction X of the heat pipe 1.

The first sintered body layer 6 is preferably formed by a sintered body of the first copper powder, and consisting of a porous material which differs from the bulk material. By configuring the first sintered body layer 6 by a porous material, since the surface area of the first sintered body layer 6 becomes larger, it is possible to efficiently evaporate the liquid-phase working fluid F_{L}. Additionally, by configuring the first sintered body layer 6 by a sintered body of copper powder, it is possible to improve the wettability with the working fluid F, and raise the thermal conductivity.

Herein, the average particle size (average primary particle diameter) of the first copper powder is not particularly limited; however, it may be in the range of 0.01 μm or more and 200 μm or less, for example. The average particle size in the present disclosure is the particle size at 50% integrated value on a volume basis, of the particle size distribution measured by a laser diffraction scattering particle size distribution measuring method. In addition, the thickness of the first sintered body layer 6 is not particularly limited; however, it may be in the range of 0.1 mm to 1 mm, for example.

### (Regarding Configuration of Second Sintered Body Layer)

The second sintered body layer 7 consists of a sintered body of a second copper powder having an average particle size larger than the first copper powder, and is a sintered body layer formed annularly over the entirety of the inner circumferential surface 2a of the container 2, in a state in which the first sintered body layer 6 is interposed with the inner circumferential surface 2a of the container 2, viewed in a transverse section of the evaporation portion 3 perpendicular to the longitudinal direction X of the heat pipe 1. Herein, the second sintered body layer 7 is laminated on the inner circumferential surface 6a of the first sintered body layer 6, and also laminated on the inner circumferential surface 2a of the container 2 on which the first sintered body layer 6 is not laminated, and these are positioned to extend in a continuous manner. Since the second sintered body layer 7 consists of a sintered body of the second copper powder having a larger average particle size than the aforementioned first sintered body layer 6, a large voids is formed inside thereof, and since this void forms a channel in which the liquid-phase working fluid F_{L} can flow, it is possible to circulate the liquid-phase working fluid F_{L} inside thereof. In addition, the second sintered body layer 7 is also a portion for which the temperature is unlikely to become high compared to the first sintered body layer 6. Therefore, the flow of the working fluid F inside the second sintered body layer 7, when viewed in the transverse section perpendicular to the longitudinal direction X of the heat pipe 1, mainly includes the flow of the liquid-phase working fluid F_{L} supplied from the condensation portion 4 toward the first sintered body layer 6 along the inner peripheral surface 2a of the container, and the flow of the gas-phase working fluid F_{g} mainly generated in the first sintered body layer 6 toward the internal space S, such as the flows shown in FIG. 2.

The arrangement length L₂ of the second sintered body layer is preferably longer than the arrangement length L₁ of the first sintered body layer 6, viewed in a longitudinal section including the longitudinal direction X of the heat pipe 1, as shown in FIG. 1A. At this time, the second sintered body layer 7 extends in a continuous manner from the inner circumferential surface 6a of the first sintered body layer 6 that is in the evaporation portion 3, until a portion of the inner circumferential surface 5a of the middle portion 5. Since the liquid-phase working fluid F_{L} suctioned to the second sintered body layer 7 at the inner circumferential surface 5a of the middle portion 5 passes through the voids formed inside of the second sintered body layer 7 to be supplied smoothly to the inner circumferential surface 6a of the first sintered body layer 6, it is thereby possible to make it harder for retention of the liquid-phase working fluid F_{L} to happen before and after the boundary between the middle portion 5 and the evaporation portion 3. In addition, since the liquid-phase working fluid F_{L} passes through the voids formed inside of the second sintered body layer 7 to flow from the inner circumferential surface 5a of the middle portion 5 towards the tip end of the evaporation portion 3 along the longitudinal direction X of the container, it is possible to reduce the contact between the liquid-phase working fluid F_{L} passing inside of the second sintered body layer 7, and the gas-phase working fluid F_{g} passing in the internal space S, and supply the liquid-phase working fluid F_{L} in a wider range of the inner circumferential surface 6a of the first sintered body layer 6 which is in the evaporation portion 3.

Herein, the flow of the working fluid F inside the second sintered body layer 7, when viewed in the longitudinal section including the longitudinal direction X of the heat pipe 1, mainly includes the flow of the liquid-phase working fluid F_{L} suctioned by the inner circumferential surface 5a of the middle portion 5 toward the tip end of the evaporation portion 3 along the longitudinal direction X of the container, and the flow of the gas-phase working fluid F_{g} generated mainly in the first sintered body layer 6 toward the internal space S.

In particular, the second sintered body layer 7 preferably terminates at any position of the middle portion 5. At this time, the second sintered body layer 7 extends so as to make contact with both the inner circumferential surface 6a of the first sintered body layer 6 and the inner circumferential surface 5a of the middle portion 5. In addition, the second sintered body layer 7 has both an outer circumferential surface 7b positioned on the inner circumferential surface 6a of the first sintered body layer 6, and an outer circumferential surface 7b′ positioned on the inner circumferential surface 5a of the middle portion 5 of the container 2. On the other hand, the second sintered body layer 7 preferably does not contact the condensation portion 4, from the viewpoint of lowering the temperature of the condensation portion 4 to prompt condensation of the working fluid F.

Herein, it is preferable to configure the liquid-phase working fluid F_{L} that has phase changed in the condensation portion 4 so as to flow toward the evaporation portion 3 by capillary force through the internal voids of the second sintered body layer 7 located in the middle portion 5, and flow from the second sintered body layer 7 toward the first sintered body layer 6 through the contact interface between the outer peripheral surface 7b of the second sintered body layer 7 and the inner peripheral surface 6a of the first sintered body layer 6. By configuring the second sintered body layer 7 in this way, the liquid-phase working fluid F_{L} is transported from the inner circumferential surface 5a of the middle portion 5 along the second sintered body layer 7 extending in the longitudinal direction X of the container 2 until a portion contacting with the first sintered body layer 6, and is evaporated from a wider range of the first sintered body layer 6. As a result thereof, by efficiently evaporating the liquid-phase working fluid F_{L}, it is possible to decrease the thermal resistance of the heat pipe 1.

The second sintered body layer 7 is configured on the inner circumferential surface 2a of the container 2 so that the liquid flow of the liquid-phase working fluid F_{L} flows at least in the internal voids of the second sintered body layer 7. At this time, the second sintered body layer 7 is preferably configured so as to substantially separate the vapor flow of the gas-phase working fluid F_{g} that changed phase in the evaporation portion 3, and the liquid flow of the liquid-phase working fluid F_{L} that changed phase in the condensation portion 4, at the position of the middle portion 5. It is thereby possible to make it less likely for unintended condensation of the gas-phase working fluid F_{g} in the evaporation portion 3 or middle portion 5 to occur, by contact between the liquid-phase working fluid F_{L} passing inside of the second sintered body layer 7 and the gas-phase working fluid F_{g} passing through the internal space S.

The second sintered body layer 7 is configured by a sintered body of the second copper powder having a larger average particle size than the first copper powder, which is a porous material. Since the pores through which the liquid-phase working fluid F_{L} can pass through are formed in the second sintered body layer 7, it is thereby possible to transport the liquid-phase working fluid F_{L} from the inner circumferential surface 5a of the middle portion 5 until the inner circumferential surface 6a of the first sintered body layer 6. Additionally, by configuring the second sintered body layer 7 by a sintered body of copper powder, it is possible to improve the wettability with the working fluid F, and raise the thermal conductivity. Therefore, the second sintered body layer 7 has a high thermal conductivity, and can exhibit a dry-out resistance in the first sintered body layer 6 in which the liquid-phase working fluid F_{L} evaporates.

Herein, the average particle size of the second copper powder (average primary particle diameter) constituting the second sintered body layer 7 is not particularly limited; however, it may be in the range of 100 μm or more and 500 μm or less, for example. In addition, the proportion of the average particle size of the second copper powder relative to the average particle size of the first copper powder is not particularly limited; however, it may be in the range of 2 or more and 5 or less, for example. On the other hand, the thickness of the second sintered body layer 7 is not particularly limited; however, it may be in the range of 0.3 mm or more and 5 mm or less, for example.

The second sintered body layer 7 preferably has an area ratio relative to the total area of the first sintered body layer 6 and the second sintered body layer 7 when viewing the evaporation portion 3 in a cross section perpendicular to the longitudinal direction X of the heat pipe 1 in the range of 50% or more and 90% or less. By increasing the area ratio of the second sintered body layer 7 in this way, since the liquid-phase working fluid F_{L} passing through the inside of the second sintered body layer 7 increases, it is possible to further raise the efficiency of circulation of the working fluid F.

### (Regarding Operating Principle of Heat Pipe)

Next, the operating principle of the heat pipe 1 will be described using the heat pipe 1 according to the first embodiment shown in FIGS. 1A, 1B, 1C and 2. Herein, the heat pipe 1 enters a state in which the liquid-phase working fluid F_{L} prior to operation is sealed in the internal space S.

First, the liquid-phase working fluid F_{L} is supplied to a portion of the inner circumferential surface 2a of the container 2 contacting with the second sintered body layer 7. The supply means of the liquid-phase working fluid F_{L} to the portion of the container 2 contacting with the second sintered body layer 7 is not particularly limited. For example, by using the capillary force occurring when the second sintered body layer 7 contacts the liquid-phase working fluid F_{L}, since it is possible to supply the liquid-phase working fluid F_{L} to the entirety of the second sintered body layer 7, it is possible to make the occurrence of dry-out unlikely to occur.

It is configured so that the liquid-phase working fluid F_{L} supplied to the portion of the inner circumferential surface 2a of the container 2 contacting with the second sintered body layer 7 is at least partially absorbed in the second sintered body layer 7, and flows in the internal voids of the second sintered body layer 7. In particular, in the case of a plurality of grooves 8 being formed in the inner circumferential surface 2a of the container 2 as described later, the liquid flow of the liquid-phase working fluid F_{L} may be configured so as to be divided into a channel passing through the plurality of grooves 8, and a channel through the internal voids of the second sintered body layer 7.

The liquid-phase working fluid F_{L} absorbed to the second sintered body layer 7 flows along the longitudinal direction X by the capillary force possessed by the second sintered body layer 7, and is absorbed in the first sintered body layer 6 in a wide range in which the second sintered body layer 7 and the first sintered body layer 6 make contact. On the other hand, the working fluid F_{L} having flowed through the grooves 8 without being absorbed to the second sintered body layer 7 is absorbed to the first sintered body layer 6 or the second sintered body layer 7 at a portion at which the groove 8 and the first sintered body layer 6 or second sintered body layer 7 are close.

Herein, the evaporation portion 3 of the heat pipe 1, when receiving heat from the heat source 9 thermally connected thereto, evaporates the liquid-phase working fluid F_{L} to change phase into the gas-phase working fluid F_{g} at the surface of the first sintered body layer 6 to which the liquid-phase working fluid F_{L} was supplied, thereby absorbing the heat received from the heat source 9 as evaporative latent heat. In particular, with this heat pipe 1, since it is possible to cause the liquid-phase working fluid F_{L} to efficiently change phase to the gas-phase working fluid F_{g} at a portion of the container 2 opposing the heat source 9 or the vicinity thereof, it is possible significantly reduce the thermal resistance of the heat pipe 1.

The gas-phase working fluid F_{g} having absorbed heat in the evaporation portion 3 flows through the vapor channel, which is the internal space S of the container 2, from the evaporation portion (heat receiving section) 3 along the longitudinal direction X of the container 2 to the condensation portion (heat radiating section) 4, whereby the heat received from the heat source 9 is transported from the evaporation portion 3 through the middle portion 5 to the condensation portion 4. At this time, the gas-phase working fluid F_{g} transported from the evaporation portion 3 through the middle portion 5 to the condensation portion 4 is unlikely to contact with the liquid-phase working fluid F_{L} passing inside of the second sintered body layer 7; therefore, it is possible to prevent the circulatory flow of the working fluid F from being disrupted by counterflow of the gas-phase working fluid F_{g}, etc. For this reason, with the heat pipe 1, it is possible to realize a superior thermal transport property.

Thereafter, the gas-phase working fluid F_{g} transported to the condensation portion 4 is made to phase change to the liquid phase by a heat exchanging means (not shown) in the condensation portion 4. At this time, the transported heat of the heat source 9 is released to outside of the heat pipe 1 as condensation latent heat. Then, the liquid-phase working fluid F_{L} which released heat in the condensation portion 4 to phase change to the liquid phase is supplied to a portion of the inner circumferential surface 2a of the container 2 contacting with the second sintered body layer 7, along the longitudinal direction X on the inner circumferential surface 2a of the container 2, whereby it is possible to form a circulatory flow of working fluid between the evaporation portion 3 and the condensation portion 4.

### SECOND EMBODIMENT

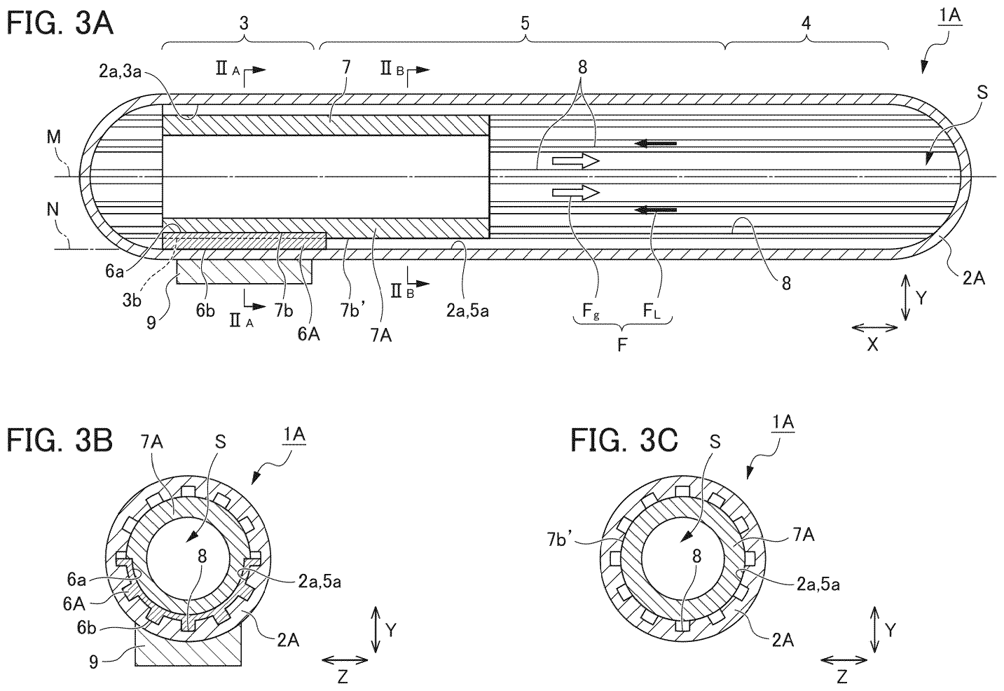

FIGS. 3A, 3B and 3C provide drawings showing the internal structure of a heat pipe according to a second embodiment, with FIG. 3A being a longitudinal section, FIG. 3B being a cross-sectional view when sectioning on the line II_{A}-II_{A} of FIG. 3A, and FIG. 3C being a cross-sectional view when sectioning on the line II_{B}-II_{B} Of FIG. 3A. It should be noted that each constituent member shown in FIGS. 3A, 3B and 3C, in the case of being the same as the constituent member of the heat pipe 1 shown in FIGS. 1A, 1B and 1C, is assigned the same reference symbol.

In the heat pipe 1 shown in the first embodiment is illustrated for a form in which the inner peripheral surface 2a of the container 2 is formed by a smooth surface; however, it is not to be limited thereto. For example, as in the heat pipe 1A shown in FIGS. 3A, 3B and 3C, a plurality of grooves 8 extending along the longitudinal direction L of the container 2A may be formed in the inner circumferential surface 2a of the container 2A. By providing such grooves 8, upon transporting the liquid-phase working fluid F_{L} inside of the heat pipe 1, it is possible to exhibit the capillary force so that the liquid-phase working fluid F_{L} migrates on the inner circumferential surface 2a of the container 2A along the grooves 8 and the second sintered body layer 7. For this reason, it is possible to promote the transport of the liquid-phase working fluid F_{L} from the condensation portion 4 to the evaporation portion 3, and thus possible to have reverse operability. Herein, reverse operability refers to the ability to exhibit a function as a heat pipe even in the case of the position of the evaporation portion 3 being higher than the position of the condensation portion 4.

These grooves 8 preferably extend in the longitudinal direction X in the inner circumferential surface 2a at least from the condensation portion 4 until a portion at which the second sintered body layer 7 is located, and more preferably continuous grooves 8 extend from the condensation portion 4 to the evaporation portion 3. Since transport of the liquid-phase working fluid F_{L} from the condensation portion 4 until a portion at which the second sintered body layer 7 is located is promoted, it is thereby possible to promote transport of the liquid-phase working fluid F_{L} to the first sintered body layer 6 which is in the evaporation portion 3, via the second sintered body layer 7. In particular, by including continuous grooves 8 from the condensation portion 4 to the evaporation portion 3, it is possible to supply the liquid-phase working fluid F_{L} to the first sintered body layer 6 located in the evaporation portion 3 through both a channel passing through the inside of the second sintered body layer 7 and a channel through the grooves 8.

The container 2A having the grooves 8 may be a grooved pipe in which the grooves 8 extending toward the longitudinal direction X of the container 2A are formed in the inner circumferential surface 2a of the container 2A. In particular, by configuring the container 2A with a grooved tube, since the capillary force for transporting the liquid-phase working fluid F_{L} is exhibited over the entire length of the container 2A, even in the case of the heat pipe 1A being installed in the posture of top heat, i.e. case of the evaporation portion 3 which is downstream of the liquid-phase working fluid F_{L} being installed above the condensation portion 4 and the middle portion 5, it is possible to facilitate the carrying out of transport of the liquid-phase working fluid F_{L} from the condensation portion 4 to the evaporation portion 3.

The opening width of these grooves 8 is not particularly limited; however, it may be set to 0.1 mm to 1 mm, for example, from the viewpoint of promoting the transport of the liquid-phase working fluid F_{L} by capillary force.

The first sintered body layer 6A of the heat pipe 1A is preferably filled to be formed also in the grooves 8 positioned in a specific area on the inner circumferential surface 2a of the container. In other words, the first sintered body layer 6A is preferably formed so as to include more to the side of the container 2A than a virtual inner circumferential surface 3b of a hypothetical case of the grooves 8 not being formed in the evaporation portion 3 of the container. More preferably, the first sintered body layer 6A is filled in part or the entirety of the longitudinal direction X of the grooves 8. In particular, the first sintered body layer 6A is preferably formed so as to contact the bottom of the groove 8, as shown in FIG. 3B. By the liquid-phase working fluid F_{L} transported along the grooves 8 contacting the first sintered body layer 6A, since it is made easier to suction to the first sintered body layer 6A, it is thereby possible to further promote evaporation of the liquid-phase working fluid F_{L}.

Herein, the inner circumferential surface of the first sintered body layer 6A is preferably configured so as to be more to the side of a center axis position M of the internal space S of the container 2A than a boundary surface position N at which a portion of the second sintered body layer 7A and a portion of the inner circumferential surface 2a of the container 2A positioned in the middle portion 5 make contact, as shown in FIG. 3A. Since at least part of the flow of the liquid-phase working fluid F_{L} flowing through the second sintered body layer 7A impinges on the first sintered body layer 6A, it is thereby possible to promote the circulation of the liquid-phase working fluid F_{L} from the second sintered body layer 7A to the first sintered body layer 6A.

In addition, the first sintered body layer 6A can be configured so that the space of the groove 8 exists between the inner circumferential surface 2a of the container 2A and the outer circumferential surface 6b of the first sintered body layer 6A. It is thereby possible to make the liquid-phase working fluid F_{L} which has phase changed in the condensation portion 4 migrate more rapidly through the grooves 8 to a position of the evaporation portion 3 at which the outer circumferential surface of the first sintered body layer 6A is present, a result of which it is possible to further promote the circulatory flow of the liquid-phase working fluid F_{L} from the condensation portion 4 to the evaporation portion 3.

The second sintered body layer 7A of the heat pipe 1A is preferably configured to substantially separate the vapor flow of the gas-phase working fluid F_{g} that has phase changed in the evaporation portion 3, and the liquid flow of the liquid-phase working fluid F_{L} that has phase changed in the condensation portion 4, and the liquid flow of the liquid-phase working fluid F_{L} is divided into a channel through the plurality of grooves 8 and a channel through the internal voids of the second sintered body layer 7A. In a portion in which the second sintered body layer 7A and the groove 8 is arranged, since it is possible to circulate more of the liquid-phase working fluid F_{L}, it is thereby possible to make it more unlikely for retention of the liquid-phase working fluid F_{L} in this portion to occur. In addition, at the portion in which the channel through the plurality of grooves 8 and the channel through the internal voids of the second sintered body layer 7 are formed in parallel, since the liquid-phase working fluid F_{L} is more strongly suctioned, it is possible to increase the circulation rate of the liquid-phase working fluid F_{L} in the middle portion 5 and the evaporation portion 3, and thereby further raise the thermal transport property of the heat pipe 1.

The average particle size (average primary particle diameter) of the second copper powder constituting the second sintered body layer 7 is not particularly limited, and may be in the range of 100 μm or more and 500 μm or less, similarly to the aforementioned heat pipe 1. On the other hand, the average particle size (average primary particle diameter) of the second copper powder constituting the second sintered body layer 7A is preferably larger than the groove width of the groove 8, from the viewpoint of not hindering the channel of the liquid-phase working fluid F_{L} formed in the groove 8.

The second sintered body layer 7A preferably does not fill the groove 8, from the viewpoint of not hindering the channel of the liquid-phase working fluid F_{L} formed in the groove 8. Herein, as a means for configuring the second sintered body layer 7A so as not to fill the groove 8, a means using, as the second copper powder, a copper powder having a larger average particle size than the aforementioned first copper powder, and a means which weakens the force acting on the copper powder to sinter, upon loading the second copper powder in the container 2.

### OTHER EMBODIMENTS

The aforementioned embodiments show cases of the container 2 extending to one side of the evaporation portion 3, and having one location for each of the condensation portion 4 and the middle portion 5; however, it is not limited to only such a configuration. For example, the container 2 may extend from the evaporation portion 3 in a plurality of directions, and the condensation portion 4 and the middle portion 5 may be provided at a plurality of locations. With the heat pipe 1, even if increasing the circulation amount of the liquid-phase working fluid F_{L} by extending the container 2 from the evaporation portion 3 in a plurality of directions, it is possible to cause the heat received from the heat source 9 as evaporative latent heat to efficiently migrate to a plurality of condensation portions.

### <Production Method of Heat Pipe>

Hereinafter, specific examples of a production method of a heat pipe will be described.

The shape of the container 2 such as the tubular container used in the heat pipe 1 can be appropriately selected from a pipe material, plate material, foil material or the like, in accordance with the shape of the heat pipe 1. There is concern over dirt, etc. adhering to the surface of the container 2 being linked to a decline in heat transfer performance of the heat pipe, and thus it is preferable to wash the surface. It is possible to perform the washing by a general method, for example, it is possible to perform by solvent degreasing, electrolytic degreasing, etching, oxidative treatment and the like.

A core rod (for example, a stainless steel core rod) having a shape which serves as a mold of the first sintered body layer 6 is inserted to be disposed at an inner central position of the container 2, then the first copper powder as a raw material of the first sintered body layer 6 is loaded into the gap portion formed between an inner circumferential surface 2a of the container 2 and an outer surface of the core rod, and the loaded first copper powder is sintered to form the first sintered body layer 6. The core rod is extracted and removed from the container 2 on which the first sintered body layer 6 was formed. Herein, from the viewpoint of providing the first sintered body layer 6 to only a specific area on the inner circumferential surface 2a of the container 2, a cutting processing or the like may be performed on the formed first sintered body layer 6.

Next, a core rod (for example, a stainless core rod) having a shape serving as the mold of the second sintered body layer 7 is inserted to be disposed at the inner central position of the container 2, then the second copper powder, which is a raw material of the second sintered body layer 7, is loaded into the gap portion formed between the inner surface of the container 2 and the outer surface of the core rod, and the loaded second copper powder is sintered to form the second sintered body layer 7. The core rod is extracted and removed from the container 2 on which the second sintered body layer 7 was formed.

Herein, it is sufficient if the sintering of the first and second copper powders, which are the raw materials of the first sintered body layer 6 and the second sintered body layer 7 respectively, is at conditions normally carried out, and is not particularly limited. As an example of the conditions for sintering, it is possible to exemplify performing the sintering by conducting heat treatment under an atmosphere of reducing gas such as hydrogen gas, or a mixed gas including hydrogen gas and an inert gas (N₂, Ar, He or the like).

After forming the first sintered body layer 6 and the second sintered body layer 7 on the container 2, the sealing port which is one end part is left and only the other end part of the container 2 is sealed, and the working fluid F is injected from the sealing port. After injecting the working fluid F, the inside of the container 2 is established in a depressurized state by conducting a degassing process such as heat deairing and vacuum deairing. Subsequently, the heat pipe 1 is produced by sealing the sealing port.

The method of sealing is not particularly limited, and it is possible to exemplify TIG welding, resistance welding, pressure welding and soldering, for example. It should be noted that the initially performed sealing (sealing of only the other end part) is a step performed in order to seal a portion other than the portion from which the gas inside escapes upon the degassing performed thereafter, and a second sealing (sealing of the sealing port) is a step performed in order to seal the portion from which the internal gas escapes upon degassing.

Although embodiments of the present invention have been described above, the present invention is not to be limited to the above-described embodiments, and it is possible to make various modifications within the scope of the present invention, including every mode encompassed by the gist of the present invention and the scope of the patent claims.

### EXAMPLES

Hereinafter, the present invention will be described in further detail based on Examples. However, the present invention is not to be limited thereto.

### Present Invention Example

A heat pipe 1B of the present invention example is an example of the heat pipe 1 of cylindrical shape having the internal structure shown in FIGS. 1A, 1B and 1C. As the container 2, a tubular container of cylindrical shape was used having a length along the longitudinal direction X of 400 mm, and a diameter (inner diameter) of 7 mm. A stainless steel core rod of a shape serving as the mold for the first sintered body layer 6B is inserted to be disposed at the inner central position of this container 2, and then a copper powder (first copper powder) having an average particle size (average primary particle diameter) of 100 μm, which is the raw material of the first sintered body layer 6B, was filled into the gap portion formed between the inner surface of a grooved tube and the outer surface of the core rod. Then, heat treatment under an atmosphere of a reducing gas was conducted on the container 2 loaded with the first copper powder to sinter the copper powder, followed by extracting and removing the core rod from the container 2. The first sintered body layer 6B consisting of copper sintered compact of 0.5 mm thickness was thereby formed in a specific area on the inner circumferential surface 2a of the container 2, more specifically, an area of 67% area ratio relative to the area of the entirety of the inner circumferential surface 2a of a portion serving as the evaporation portion 3, including the entirety of an area of the inner circumferential surface 2a constituting the portion opposing the heat source 9. Herein, the length of the area constituting the portion of the inner circumferential surface 2a of the container 2 opposing the heat source 9 when viewing the portion of the heat pipe 1B to be the evaporation portion 3 in a transverse section perpendicular to the longitudinal direction X is set at 50% of the entire length of the inner circumferential surface 2a, and the area in which the first sintered body layer 6B is formed is arranged so that the size of the area on both sides becomes equal to the area of the inner circumferential surface 2a constituting the portion opposing the heat source 9 and the area on the inner circumferential surface 2a adjacent to both sides thereof. Further, in the inner circumferential surface 2a of the container 2, an area constituting a portion opposing the heat source 9 is provided in a range from a position of 15 mm to a position of 55 mm from a tip end on the evaporation portion 3 side of the container 2, viewed in a longitudinal section including the longitudinal direction X of the heat pipe 1B, and a range to a position of 55 mm from a tip end on the evaporation portion 3 side is established as the evaporation portion 3. For this reason, the longitudinal direction dimension L₀ of the evaporation portion 3 is 55 mm. In addition, viewing in a longitudinal section including the longitudinal direction X of the heat pipe 1B, the first sintered body layer 6B was provided in a range to a position 60 mm from the tip end of the evaporation portion 3 side. For this reason, the arranged length L₁ along the longitudinal direction X of the first sintered body layer 6B is 60 mm.

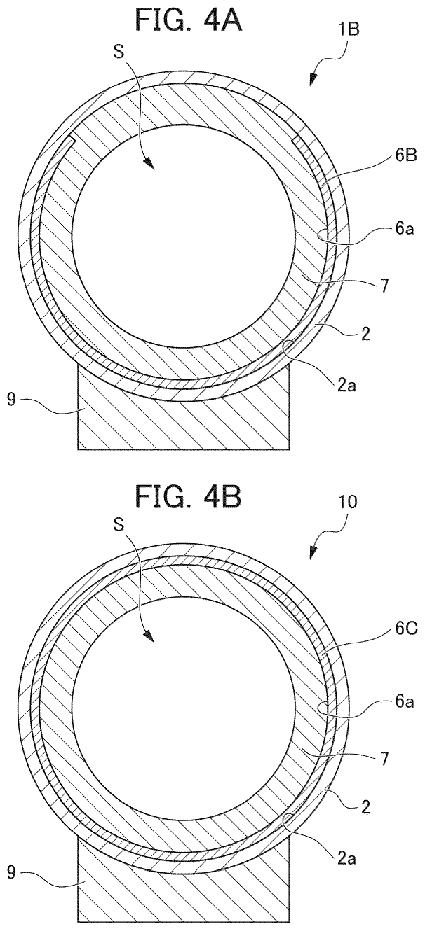

Next, a stainless steel core rod having a shape serving as the mold of the second sintered body layer 7 was inserted to be disposed in the inner central position of the container 2, and then copper powder (second copper powder) having an average particle size (average primary particle diameter) of 200 μm, which is the raw material of the second sintered body layer 7, was loaded into the gap portion formed between the inner surface of the grooved tube and the outer surface of the core rod. Then, heat treatment under an atmosphere of reducing gas was conducted on the container 2 filled with the second copper powder to sinter the copper powder, followed by extracting to remove the core rod from the container 2. As a result, the second sintered body layer 7 made of a copper sintered body having a length along the longitudinal direction X of 250 mm and an inner diameter of the inner circumferential surface of 5 mm (thickness of portion where the first sintered body layer 6B is formed is 0.5 mm, and thickness of portion where the first sintered body layer 6B is not formed is 1.0 mm) was formed on the entirety of the inner peripheral surface 2a of the container 2 as viewed in a transverse section perpendicular to the longitudinal direction X, in a state in which the first sintered body layer 6B was partially interposed by the inner circumferential surface 2a of the container 2, from the tip end of the container 2 on the evaporation portion 3 side to the middle portion 5, as shown in FIG. 4A.

After forming the first sintered body layer 6 and the second sintered body layer 7, the sealing port which is one end part was left, and only the other end of the container 2 was sealed, and water which is the liquid-phase working fluid F (L) was injected from the sealing port. Next, the inside of the container 2 was established in a depressurized state by degassing, followed by sealing the sealing port to produce the heat pipe 1.

### COMPARATIVE EXAMPLE

The heat pipe 10 of the comparative example formed a first sintered body layer 6C consisting of a copper sintered body of 60 mm arrangement length along the longitudinal direction X and 0.5 mm thickness on the entirety of the inner circumferential surface 2a of the container 2, as shown in FIG. 4B. Otherwise, the heat pipe was produced to be made in the same configuration as the heat pipe of the present invention example.

Herein, FIGS. 4A and 4B provide transverse sections showing the internal structure of heat pipes according to the present invention example and the comparative example, with FIG. 4A being a transverse section of the heat pipe 1 according to the present invention example, and FIG. 4B being a transverse section of the heat pipe 10 according to the comparative example.

### (Performance Evaluation)

Performance evaluation of the heat pipes was carried out under the following conditions.
1. A heater block (calorific value of 50 W to 250 W) as the heat source was attached on an outer surface of the evaporation portion (heat receiving portion), which is one end side portion of the heat pipe.
2. The heat exchanging means was attached to the condensation portion (heat radiating portion), which is the other end side portion of the heat pipe.
3. A heat insulating material was attached to the middle portion between the evaporation portion and the condensation portion to form a heat insulating portion.
4. While gradually increasing the heat input to the evaporation portion from 50 W in the state installed in the horizontal direction, the magnitude of the heat input when the difference between the temperature of the heat source and the temperature of the condensation portion reached a minimum was measured, and this measured heat input was defined as the maximum heat transport amount Qmax (W).
5. The difference between the temperature of the heat source and the temperature of the condensation portion was measured, and a value obtained by dividing this difference by the heat input was defined as the thermal resistance (° C./W).

Among these, the result of the maximum heat transport amount Qmax was expressed as the relative value when defining the comparative example in which the first sintered body layer 6 was formed on the entire surface of the inner circumferential surface 2a of the container 2 as a reference (index ratio of 100). The results are shown in the “relative value of maximum heat transport amount” column of Table 1.

TABLE 1

| | Tubular container (container) | | | | | |
|---|---|---|---|---|---|---|
| | | | First sintered body layer | | | |
| | | | | Area ratio of | | |
| | | | | area in which | | |
| | | | | forming the | | |
| | | | | first sintered | | |
| | | | | body layer | | |
| | | | | relative to | | |
| | | | Average | area of | | |
| | | | particle | entire inner | | |
| | | | size of | circumferential | | |
| | | | first | surface of | Inner | |
| | Diameter | Length of | copper | portion of | diameter | Length along |
| | (inner | tubular | powder | tubular | of | longitudinal |
| | diameter) | container | constituting | container | first | direction X |
| | of | along | first | serving as | sintered | of first |
| | tubular | longitudinal | sintered | evaporation | body | sintered |
| | container | direction X | body layer | portion | layer | body layer |
| | [mm] | [mm] | [μm] | [%] | [mm] | [mm] |
| Present | 7 | 400 | 100 | 67 | — | 60 |
| Invention | | | | | | |
| Example | | | | | | |
| Comparative | 7 | 400 | 100 | 100 | 6 | 60 |
| Example | | | | | | |

| | Tubular container (container) | | | | |
|---|---|---|---|---|---|
| | Second sintered body layer | | | | |
| | Average | | | | Results and |
| | particle | | | | evaluation |
| | size of | | | | of |
| | second | Inner | | | maximum heat |
| | copper | diameter | Length along | | transport |
| | powder | of | longitudinal | Drawing of | amount |
| | constituting | second | direction X | heat pipe | Absolute |
| | second | sintered | of second | configuration | value of |
| | sintered | body | sintered | (transverse | maximum heat |
| | body layer | layer | body layer | sectional | transport |
| | [μm] | [mm] | [mm] | view) | amount |
| Present | 200 | 5 | 250 | FIG. 4A | 128 |
| Invention | | | | | |
| Example | | | | | |
| Comparative | 200 | 5 | 250 | FIG. 4B | 100 |
| Example | | | | | |

As a result, the heat pipe 1 of the present invention example had an absolute value for the maximum heat transport amount Qmax of 128, when defining the comparative example forming the first sintered body layer 6 on the entire surface on the inner circumferential surface 2a of the container 2 as a reference (index ratio of 100).

Therefore, the heat pipe 1 of the present invention example was found to have a high thermal transport property, due to having a high absolute value for the maximum heat transport amount Qmax compared to the heat pipe 10 of the comparative example.

### EXPLANATION OF REFERENCE NUMERALS

1, 1A heat pipe
2, 2A container
2a inner circumferential surface of container
3 evaporation portion
3a inner circumferential surface of evaporation portion of container
3b virtual inner circumferential surface of evaporation portion of container
4 condensation portion
5 middle portion
5a inner circumferential surface of middle portion of container
6, 6A first sintered body layer
6a inner circumferential surface of first sintered body layer
6b outer circumferential surface of first sintered body layer
7, 7A second sintered body layer
7b outer circumferential surface of second sintered body layer positioned over inner circumferential surface of first sintered body layer
7b′ outer circumferential surface of second sintered body layer positioned over inner circumferential surface of middle portion of container
8 groove
9 heat source
10 heat pipe of comparative example
F working fluid
F_{L} liquid-phase working fluid
F_{g} gas-phase working fluid
L₀ longitudinal direction dimension of evaporation portion
L₁ arrangement length of first sintered body layer
L₂ arrangement length of second sintered body layer
M center axis position of internal space of container
N boundary surface position located in middle portion at which a portion of second sintered body layer and a portion of inner circumferential surface of the container contact
S internal space
X longitudinal direction of container
Y thickness direction of container
Z depth direction of container

1. A heat pipe comprising a container having an internal space in which a working fluid is sealed, the container including:
a evaporation portion that evaporates a liquid-phase working fluid to change phase to a gas-phase working fluid;
a condensation portion arranged at a position that is separated from the evaporation portion, and condenses the gas-phase working fluid to change phase into the liquid-phase working fluid; and
a middle portion positioned between the evaporation portion and the condensation portion,
wherein, viewing a transverse section of the heat pipe in the evaporation portion, the heat pipe includes:
a first sintered body layer consisting of a sintered body of a first copper powder, and formed in a specific area on an inner circumferential surface of the container; and
a second sintered body layer consisting of a sintered body of a second copper powder having a larger average particle size than the first copper powder, and formed annularly over an entirety of an inner circumferential surface of the container, in a state in which the first sintered body layer is interposed between the inner circumferential surface of the container and the second sintered body layer.

2. The heat pipe according to claim 1, wherein, viewing in a longitudinal section including a longitudinal direction of the heat pipe,
an arrangement length of the first sintered body layer is longer than a longitudinal direction dimension of the evaporation portion, and
an arrangement length of the second sintered body layer is longer than the arrangement length of the first sintered body layer.

3. The heat pipe according to claim 2, wherein the second sintered body layer terminates at any position of the middle portion.

4. The heat pipe according to claim 3, wherein the heat pipe is configured so that a liquid-phase working fluid that has phase changed in the condensation portion flows toward the evaporation portion by way of capillary force through internal voids of the second sintered body layer located in the middle portion, and flows through a contact interface between an outer circumferential surface of the second sintered body layer and an inner circumferential surface of the first sintered body layer from the second sintered body layer towards the first sintered body layer.

5. The heat pipe according to claim 1, wherein the specific area includes an area of an inner circumferential surface that constitutes a portion of the container which opposes a heat source.

6. The heat pipe according to claim 1, wherein a plurality of grooves extending along a longitudinal direction of the container is formed in the inner circumferential surface of the container.

7. The heat pipe according to claim 6, wherein the first sintered body layer is filled to also form in the grooves located in the specific area.

8. The heat pipe according to claim 6, wherein the second sintered body layer substantially separates vapor flow of a gas-phase working fluid that has phase changed in the evaporation portion, and a liquid flow of a liquid-phase working fluid that has phase changed in the condensation portion, and the liquid flow is divided into a channel passing through the plurality of grooves, and a channel through internal voids of the second sintered body layer.
